(19) United States
(12) Patent Application Publication
(10) Pub. No.: US 2010/0132757 A1
(43) Pub. Date: Jun. 3, 2010

(54) SOLAR ENERGY SYSTEM

(75) Inventors: JIN-MAN HE, Tao-Yuan (TW); YEN-TING YI, Tao-Yuan (TW)

Correspondence Address: WPAT, PC;INTELLECTUAL PROPERTY ATTORNEYS, 7225 BEVERLY ST., ANNANDALE, VA, 22003, US

(73) Assignee: Chung Yuan Christian University, Tao-Yuan (TW)

(21) Appl. No.: 12/325,388

(22) Filed: Dec. 1, 2008

(51) Int. Cl. H01L 31/042

(52) U.S. Cl. 136/244

(57) ABSTRACT

The present invention discloses a solar energy system that uses perturbation and observation method to achieve maximum power point (MPP) tracking in conjunction with interleaving operations of sets of converters to maximize solar energy conversion.

### BACKGROUND OF THE INVENTION

### Description of the Prior Art

Owing to the global energy shortage, growing environmental awareness, scarcity of fossil energy and uncertainty in nuclear power, seeking and developing alternative energy have now become one of the major policies for many countries. Alternative energy is a term generally used for an energy source that is other than coal, petroleum, natural gas and nuclear energy, including wind, sun, geothermal energy, sea water temperature difference, waves, tides, the Black Stream, biomass, fuel cell and the like. Among these, wind energy, solar energy and fuel cells have drawn the most attention in terms of application and research value. Currently, solar energy can be categorized into two types, namely, thermal and photovoltaic. Thermal solar energy produced by the sun rays is often used for heating water. While photovoltaic (PV) solar energy exploits the physical characteristics of the semiconductors, which converts light into electricity. The magnitude of PV solar energy depends on ambient conditions and is not fixed over time. Thus, special control is needed to achieve the maximum output power from PV solar energy no matter how surroundings are changed.

PV solar energy is a clean and natural energy source that becomes a likely candidate for solving the energy crisis of today. PV cells are photoelectric elements capable of energy conversion. The basic structure of which is consisted of a P-type and an N-type semiconductor joined together. The most common material for semiconductor is “silicon”, which is non-conductive, but if impurities are added to the semiconductor, P- and N-type semiconductors can be created depending on the kind of impurities added. Since holes exist in P-type semiconductors, while free electrons exist in N-type semiconductors, there will a potential difference. When sun light strikes the cells, electrons are excited from the silicon atoms, creating a flow between electrons and holes, these flowing electrons and holes will be affected by the internal potential and attracted to the N- and P-type semiconductors, respectively. As a result, they will be concentrated at opposite ends. If electrodes are connected from the outside, a loop is formed. This is basically how PV cells generate electricity.

However, the high cost and low efficiency of these solar cells or PV cells are the bottlenecks to their development. Thus, one of the main focuses in the solar energy field today is to maximize the power generated per unit cell.

### SUMMARY OF THE INVENTION

In view of the prior art and the needs of the related industries, the present invention provides a solar energy system that solves the abovementioned shortcomings of the conventional.

One objective of the present invention is to exploit maximum solar energy utilization. Conventionally, in the maximum power point tracking technique, the energy produced by the solar energy system during switch-off period of the switch in the converter is not used. Accordingly, the present invention discloses a solar energy system, which includes a solar panel, a plurality of converters and a controller. The solar panel can convert light into electricity. The plurality of converters is electrically coupled with the solar panel for providing electricity to a load. The controller is electrically coupled with the plurality of converters for controlling the respective duty cycles of switches of the plurality of converters.

### BRIEF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1 is a schematic diagram of a solar energy system according to a first embodiment of the present invention;

FIG. 2 is a schematic diagram of a solar energy system according to a second embodiment of the present invention;

FIG. 3 is a diagram depicting the system structure of a first example of the present invention;

FIG. 4 is a diagram depicting a voltage feedback circuit of the first example of the present invention;

FIG. 5 is a diagram depicting a current sensing circuit of the first example of the present invention;

FIG. 6 is a diagram depicting an internal structure of TLP250 of the first example of the present invention;

FIG. 7 is a diagram depicting the pin configuration of TLP250 of the first example of the present invention;

FIG. 8 is a diagram depicting a circuit for providing independent power source to a photocoupling isolating circuit of the first example of the present invention;

FIG. 9 is a diagram depicting circuit layout of PIC18F452 chip of the first example of the present invention;

FIG. 10 is a diagram depicting a physical realization of a PIC18F452 chip of the first example of the present invention;

FIG. 11 is a diagram depicting a dead-time generating circuit of the first example of the present invention;

FIG. 12 is a diagram depicting an internal structure of CD4069 of the first example of the present invention;

FIG. 13 is a waveform of the dead-time generating circuit of the first example of the present invention;

FIG. 14 is a diagram depicting MPPT program flow of the perturbation and observation method of the first example of the present invention;

FIG. 15 is a schematic diagram of the overall system structure of the first example of the present invention;

FIG. 16 is circuit design diagram depicting voltage and current feedback circuits of the first example of the present invention;

FIG. 17 is a diagram depicting a physical realization of the voltage and current feedback circuits of the first example of the present invention;

FIG. 18 is a diagram depicting the MPPT main circuit of the first example of the present invention;

FIG. 19 is a layout depicting a buck-boost main circuit of the first example of the present invention;

FIG. 20 is a diagram depicting a physical realization of the buck-boost main circuit of the first example of the present invention;

FIG. 21 is a schematic diagram of the overall system structure of the first example of the present invention;

FIG. 22 is a circuit diagram depicting IsSpice system simulation of the first example of the present invention;

FIG. 23 is a diagram showing simulated waveforms of Vgs and IL of a first set of buck-boost converter of the first example of the present invention;

FIG. 24 is a diagram showing simulated waveforms of a 30V input and a 17V output of the first example of the present invention;

FIG. 25 is a diagram showing simulated waveforms of Vgs and IL of a second set of buck-boost converter of the first example of the present invention;

FIG. 26 is a diagram showing simulated waveforms of a 30V input and a 43V output of the first example of the present invention;

FIG. 28 is a diagram illustrating a maximum energy utilization design combing interleaved control operations of the first example of the present invention;

FIG. 29 is a drawing illustrating photovoltaic characteristics of the first example of the present invention;

FIG. 30 is a circuit diagram depicting a buck-boost converter of the first example of the present invention;

FIG. 31 is a diagram depicting waveforms of Vgs and Vds of a switch of the first example of the present invention;

FIG. 32 is a diagram depicting waveforms of Vgs and IL with irradiance of 40K Lux of the first example of the present invention (current ripple with peak current value of 1.76 A and trough current value of 1.56 A);

FIG. 33 is a diagram depicting waveforms of Vgs and IL of the first set of converter according to the first example of the present invention (current ripple with peak current value of 2.5 A and trough current value of 1.75 A);

FIG. 34 is a diagram depicting waveforms of Vgs and IL of the second set of converter according to the first example of the present invention (with peak current value of 4.5 A and trough current value of 4.1 A);

FIG. 35 is a diagram showing waveforms of an output voltage of 75V and an output current of 3.9 A according to the first example of the present invention;

FIG. 36 is an oscilloscope used for measurement during implementation of the first example of the present invention; and

FIG. 37 is a luxmeter and a switch at the solar energy input end according to the first example of the present invention.

### DETAILED DESCRIPTION OF THE PREFERRED EMBODIMENTS

The present invention is directed to a. Detailed steps and constituents are given below to assist in the understanding the present invention. Obviously, the implementations of the present invention are not limited to the specific details known by those skilled in the art. On the other hand, well-known steps or constituents are not described in details in order not to unnecessarily limit the present invention. Detailed embodiments of the present invention will be provided as follow. However, apart from these detailed descriptions, the present invention may be generally applied to other embodiments, and the scope of the present invention is thus limited only by the appended claims.

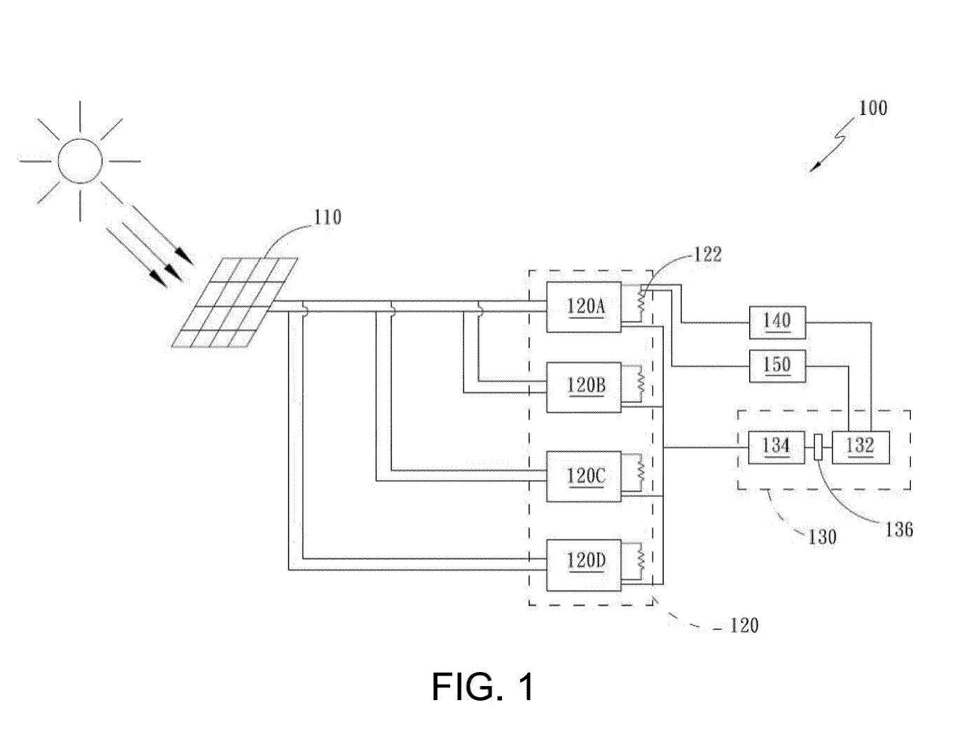

Referring to FIG. 1, a solar energy system 100 according to a first embodiment of the present invention is disclosed, which includes a solar energy plate 110, a plurality of converters 120 and a controller 130. The solar energy plate 110 can convert light into electricity. The solar energy plate 110 is electrically coupled with the plurality of converters 120, which supply electricity to a load 122 after converting. The plurality of converters 120 are electrically coupled to the controller 130, which controls the duty cycles of the converters 120. When the controller 130 switches on a converter 120A, then the rest of the converters (120B, 120C and 120D) are switched off. The plurality of converters 120 can be selected from one or a combination of the above of the following types: buck, boost, buck-boost, cuk, flyback, forward, push-pull, Sheppard-Taylor, half-bridge and full-bridge.

In this embodiment, the controller 130 includes at least one single chip 132 and at least one photocoupling isolating circuit 134. The solar energy system 100 further includes a voltage feedback circuit 140 and a current feedback circuit 150, which are coupled to an arbitrary converter (one of 120A, 120B, 120C and 120D) and the single chip 132. In addition, the solar energy system 100 further includes a dead-time generating circuit 136, which is electrically coupled to the single chip 132.

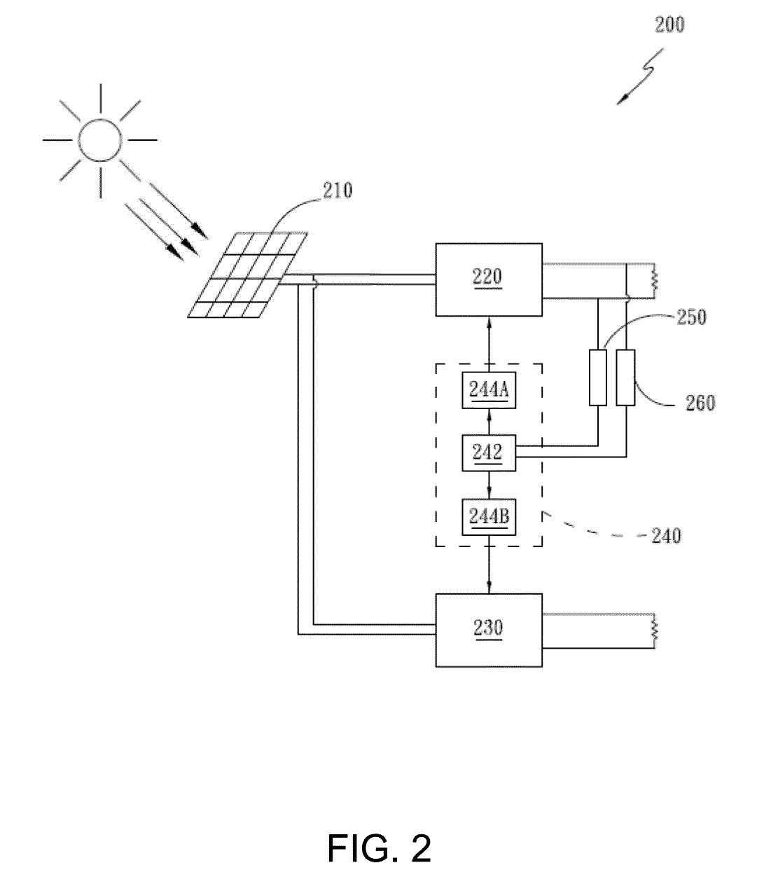

Referring to FIG. 2, a solar energy system 200 according to a second embodiment of the present invention is disclosed, which includes a solar energy plate 210, a first converter 220, a second converter 230 and a controller 240. The solar energy plate 210 converts light into electricity. The first converter 220 is electrically coupled to the solar energy panel 210, while the second converter 230 is electrically coupled to the first converter 220 in a parallel manner. The controller 240 is electrically coupled to both the first and second converters 220 and 230 for controlling the duty cycles thereof. When the controller 240 switches on the first converter 220, the second converter 230 is switched off. On the contrary, when the controller 240 switches off the first converter 220, the second converter 230 is switched on. The first and second converters can be selected from one of the following types: buck, boost, buck-boost, cuk, flyback, forward, push-pull, Sheppard-Taylor, half-bridge, full-bridge and a combination of the above.

In this embodiment, the controller 240 includes at least one single chip 242 and at least one photocoupling isolating circuit 244. Preferably, the controller 240 includes a single chip 242, a first photocoupling isolating circuit 244A and a second photocoupling isolating circuit 244B, wherein the single chip 242 is electrically coupled to both the first and second photocoupling isolating circuit 244A and 244B. The first photocoupling isolating circuit 244A is electrically coupled to the first converter 220, while the second photocoupling isolating circuit 244B is electrically coupled to the second converter 230. The single chip 242 sends a first driving signal to the first photocoupling isolating circuit 224A, and a second driving signal to the second photocoupling isolating circuit 224B. The first driving signal and the second driving signal are out of phase.

The solar energy system 200 further includes a voltage feedback circuit 250 and a current feedback circuit 260. The voltage feedback circuit 250 and the current feedback circuit 260 are both electrically coupled to the first converter 220 and the single chip 242. In addition, the solar energy system 200 further includes a dead-time generating circuit (not shown), which is electrically coupled to the single chip 242.

The single chip 242 sends a first driving signal to the first photocoupling isolating circuit 244A. Upon receiving the first driving signal, the first photocoupling isolating circuit 244A generates a light source. The on and off of the first converter 220 is controlled by the intensity of the light source. The first driving signal can be a pulse width modulation (PMW) signal.

The single chip 242 sends a second driving signal to the second photocoupling isolating circuit 244B. Upon receiving the second driving signal, the second photocoupling isolating circuit 244B generates a light source. The on and off of the second converter 230 is controlled by the intensity of the light source. The second driving signal can be a pulse width modulation (PMW) signal. The first and second driving signals are simultaneously sent.

A third embodiment of the present invention discloses method for producing power using the solar energy system of the present invention, including three steps, namely, a photovoltaic step, a electricity conversion step and a determination step. First, the photovoltaic step is performed by converting light into electricity via a solar energy plate. Then, the electricity conversion step is performed, whereby two converters are alternately used to provide electricity to a load. The two converters are a first and a second converter. Finally, the determination step is performed, in which a controller controls the duty cycle of the first converter after receiving voltage and current transmitted from the first converter. When the controller switches on the first converter, the second converter is switched off, and vice versa. The above determination step performs computations using the voltage and current received by the controller from the first converter, in order to find the best duty cycle value of the first converter, thereby obtaining the maximum power throughput.

### EXAMPLE 1

The present invention discloses a solar energy system for maximizing energy utilization, wherein a maximum power point tracker is implemented and described. This example is discussed in context of power generated during switch-off time through interleaved operations, including the design of feedback circuit, photocoupling isolating circuit and single chip PIC18F452 program.

### 1. Introduction of Solar Photovoltaic Apparatus

The solar photovoltaic (PV) system adopted by the present invention is a 900 W independent solar PV system, the specifications of which are as follow:

A. The peak capacity of the system is 900 W (under conditions of temperature of 25° C., irradiance of 1 kW/m2 and spectrum of 1.5 AM). The system is consisted of 12 pieces of monocrystalline silicon photovoltaic plates. Every four pieces are serially connected in a set, and then three sets are combined in parallel.

B. Orientation of solar PV panels: facing southwest. The panels can be tilted at angles of elevation from 11° to 28°. Since the power efficiency of the solar power system is strongly related to the irradiance received by the solar PV panels, and since the sun slightly shifts towards south or north over the year, irradiating angle of the sun may vary. The solar cell array should be adjusted accordingly to receive the maximum irradiance. According to the solar panels used in the present invention, it is observed that the power efficiency is the best when the solar array is tilted at an angle of 25° in February, while in April, 20° is the best. Furthermore, in February, the irradiance is 600 W/m2, and the power efficiency would degrade significantly when the angle of is made lower than 20°. While in April, the irradiance is 700 W/m2, the effect of variation in angles is not so significant. Thus, in this experiment, the angle is adjusted to about 20°, so as to allow the system to achieve maximum power efficiency.

### 2. Maximum Power Point Tracking System Structure and Internal Circuit Design

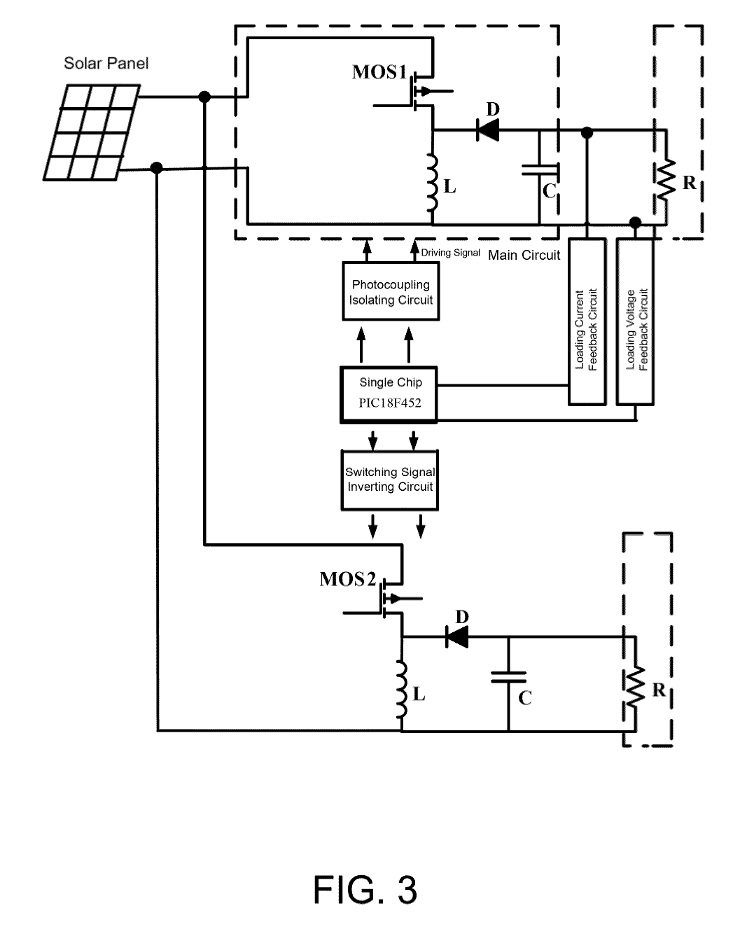

The present invention uses perturbation and observation method to achieve maximum power point (MPP) tracking. In actual circuit design, the loading voltage and loading current of the solar PV system has to be feedback to the single chip (PIC18F452) for calculation of voltage and current, in order to obtain the duty cycle required by the power switch. As a result, the power switch can be operated precisely in the desired manner later on. FIG. 3 is a diagram depicting the overall system structure of the present invention, including a solar panel, a main circuit (buck-boost DC-DC converter), loading, a voltage feedback circuit, a current feedback circuit, a single chip (PIC18F452), an photocoupling isolation circuit. The following sub-sections will be dedicated to describing the circuit design and implementation of the voltage feedback circuit, the current feedback circuit, the photocoupling isolation circuit, a driving circuit for power switches and a microcontroller.

### 2.2 Design of Voltage Feedback Circuit

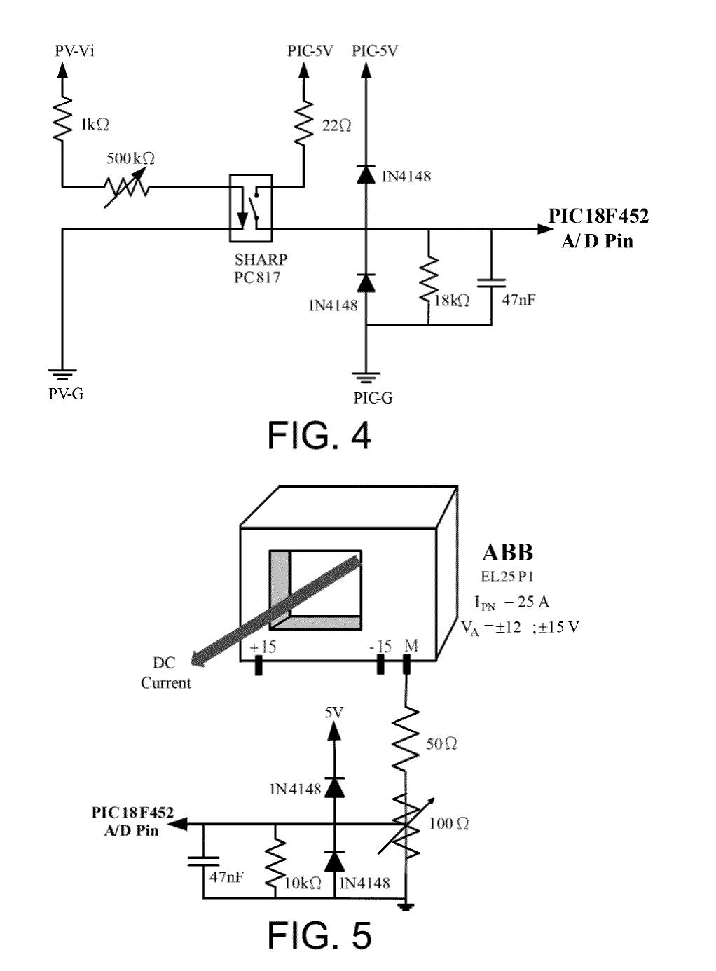

Since a feedback loading voltage is required for power determination during MPP tracking, the present invention adopts an IC chip, for example, PC817 manufactured by Sharp Corporation for voltage feedback and isolation. This IC chip linearly reduces and feedback the loading voltage to the single chip in a light transmission manner. In order to keep the voltage in a range (0˜5V) acceptable by the single chip, some limiting diodes are added into the design to clamp the output voltage within 5V. A 1 kΩ resistor and a 500 KΩ variable resistor are connected in series to a first pin on the PC817 for converting voltage into driving current of the light, such that voltage is linearly reduced to a level acceptable by the single chip, while achieving isolated feedback. An exemplary circuit diagram is shown in FIG. 4.

### 2.2 Design of Current Feedback Circuit

In terms of design, a Hall element is used as current sensing elements. Although it is slightly more expensive, it has good characteristics and no loss. The design of the circuit is shown in FIG. 5. The Hall element requires +15V and −15V driving power, and its M pin is a voltage diving point. Its amplifying ratio can be designed by adjusting the variable resistor and the number of turns of the coil, and DC current is converted into a voltage signal and sent to the A/D pin of the PCI18F452 chip. Some limiting diodes should be added to the design to clamp the voltage under 5V, which is the tolerable voltage range of the single chip.

### 2.3 Design of Driving and Isolating Circuit for Power Switch

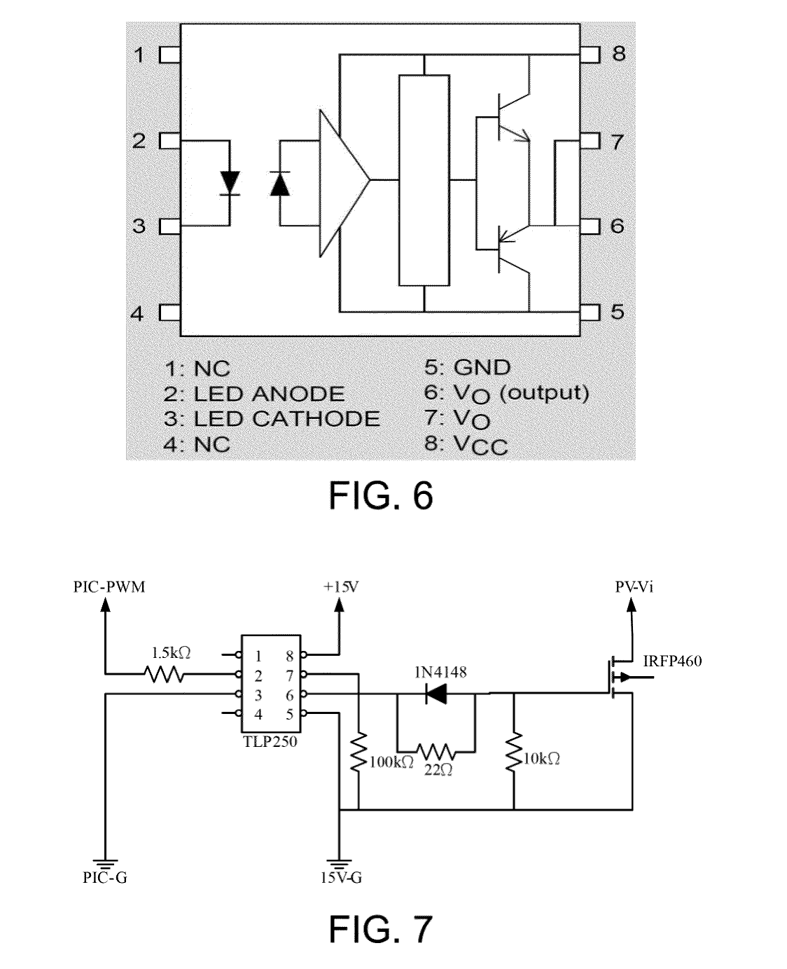

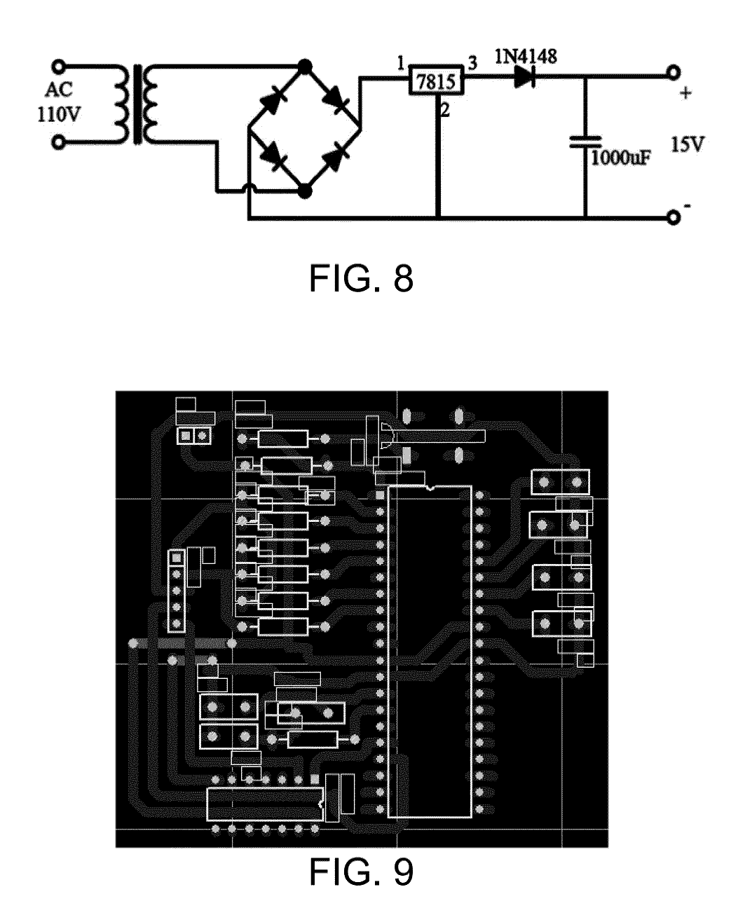

Since the driving signal has to be isolated from the main circuit, also, the driving capacity of the PWM driving voltage of the single chip has to be enhanced in order to drive MOSFET, a photocoupler such as a TLP250 photocoupler manufactured by Toshiba is used for constructing an isolating and driving circuit. This IC chip uses light as the transmitting signal, such that an input current is isolated from the triggering power via light, avoiding shortage resulted from a common ground. Table 1 is an introduction of TLP250 photocoupler. FIGS. 6 and 7 are diagrams showing the internal structure and pin configuration of the TLP250 photocoupler, respectively. FIG. 8 is a circuit diagram depicting an independent power required for the isolating and driving photocoupler circuit.

TABLE 1
Introduction of TLP250 Photocoupler

| | TLP250 Photocoupler |
|---|---|
| Working principle | Use light as transmitting signal. |
| | Input current flows through LED |
| | and generates light. Output end is |
| | a photodetector that generates |
| | power depending on the intensity |
| | of light. |
| Advantages | 1. Use light as transmission |
| | medium. Total electric isolation. |
| | 2. Capable of simplex |
| | transmission, CMRR, |
| | non-contact, long life. |
| | 3. Cheap and small. |
| | 4. Easily compatible with |
| | integrated circuits |
| Disadvantages | 1. Slow switching due to |
| | phototransistor switching time. |
| | 2. Secondary side circuit needs |
| | auxiliary power from |
| | photocoupler. |

### 2.4 Circuit Design and Layout of Single Chip (PIC18F452)

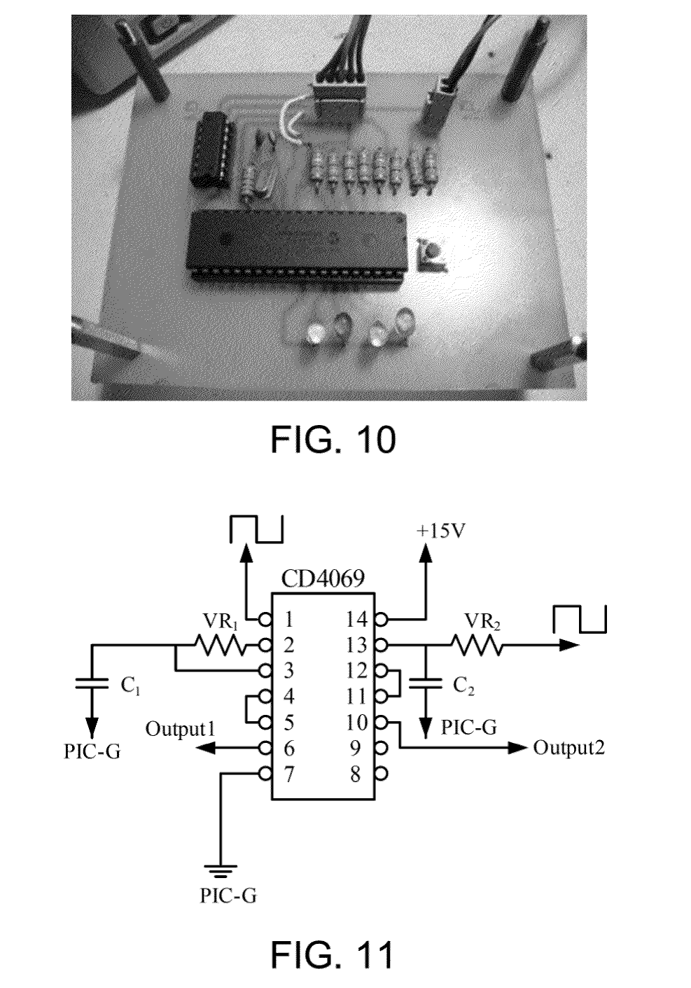

The single chip (PIC18F452) requires an additional external oscillator (20 MHz). The oscillator and the capacitor should be as close to the chip as possible to avoid external noise interference. Current-limiting resistors should be added to the voltage and current feedback circuits to avoid large current that may destroy the chip. The circuit layout and physical realization are shown in FIGS. 9 and 10, respectively.

### 2.5 Design of Dead-Time Generation Circuit

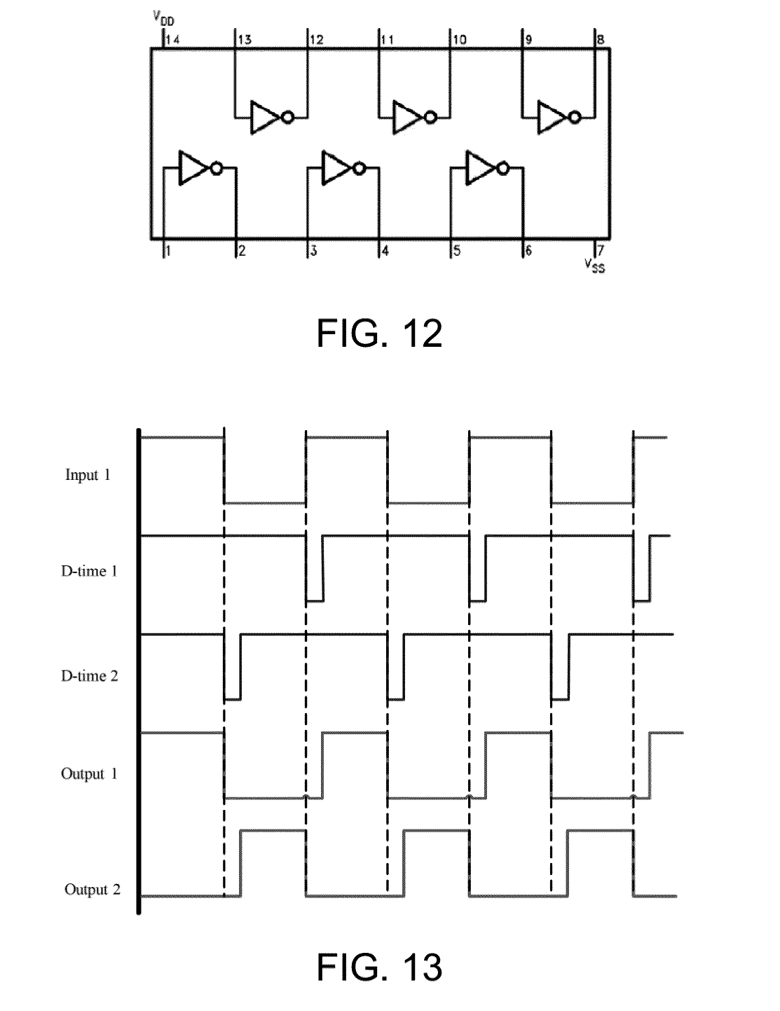

The present invention employs two active switches. In order to avoid simultaneously turning on the two power switches as a result of a propagation delay of the respective switching driving circuit, a time-delay (dead-time) circuit is usually added. Accordingly, the control signals for the two switches are designed to be complementary, and a dead-time generating circuit is added to generate a dead time to ensure the accuracy of the voltage and current values. FIG. 11 is a dead-time generating circuit, mainly consisting of a logic IC 4069; FIG. 12 is an diagram depicting the internal structure of IC 4069; FIG. 13 is diagram showing the waveform of the dead-time generating circuit, wherein the input signal is a PWM signal, and D-time1 and D-time2 are determined by RC values, which are in turn adjusted by variable resistors VR1 and VR2, respectively. Output1 and Output2 are the triggering signals for the two switches. In this way, error in voltage and current measurements due to short overlapping period of the switches can be eliminated.

### 3. Program Flow for PIC18F452 Using Perturbation and Observation Method

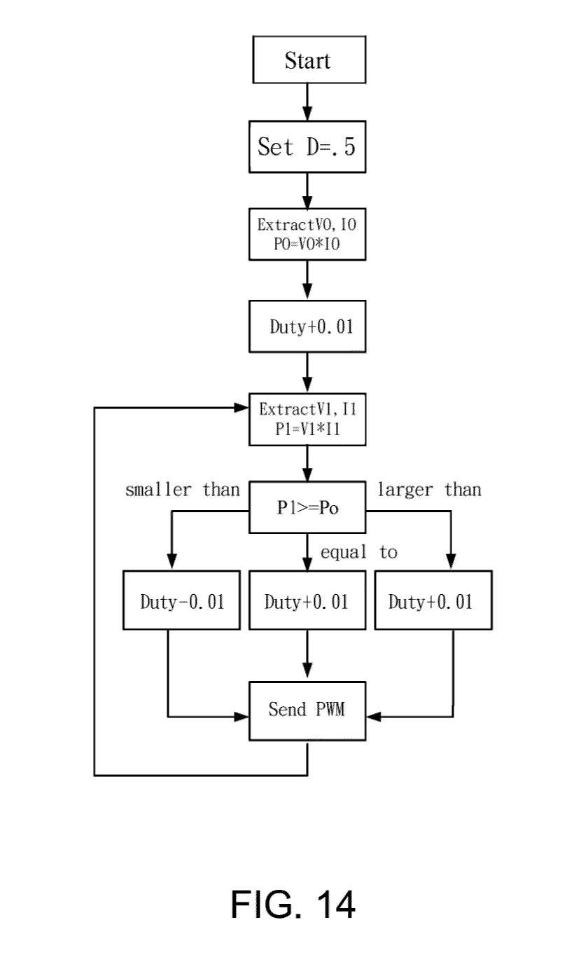

The present invention uses perturbation and observation method for maximum power point tracking. The loading voltage and current of the photovoltaics are extracted by the built-in A/D converter in the single chip PIC18F452 for determining the best duty cycle required for the power switches, thereby obtaining the maximum power transmission. The flow of the program is as shown in FIG. 14.

### 4. Circuit and Physical Diagrams for Overall Maximum Power Point Tracking System

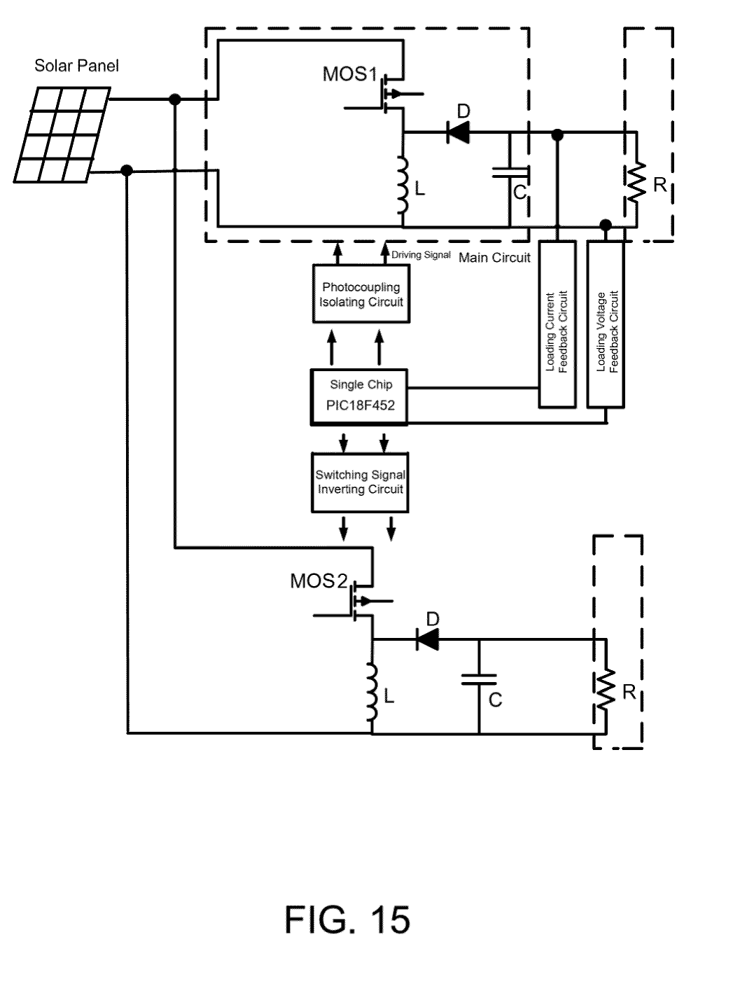

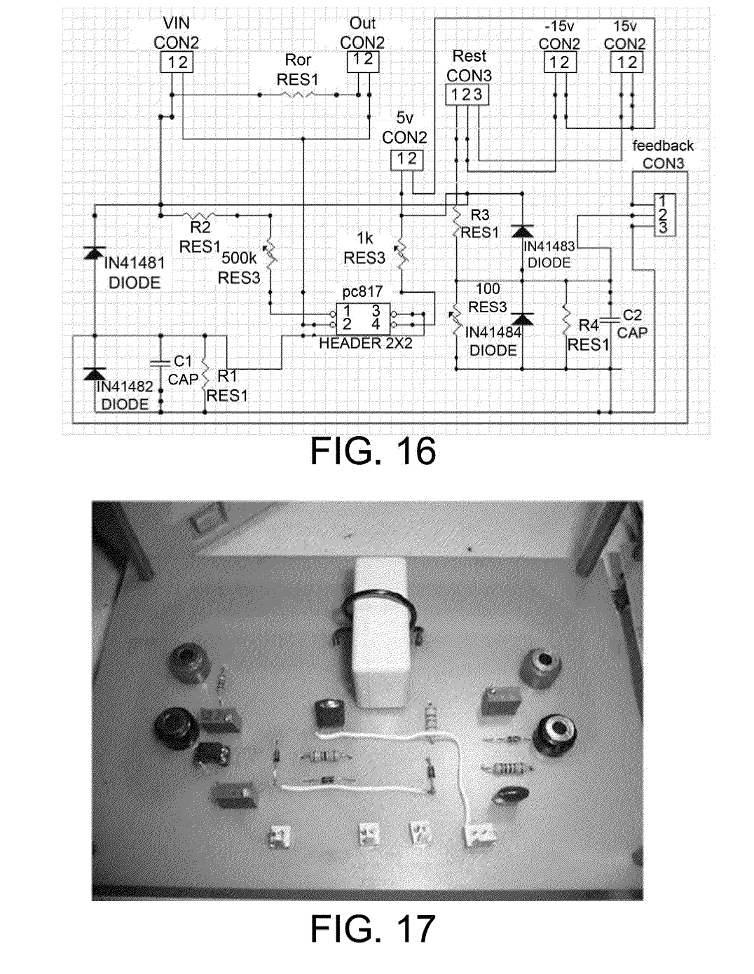

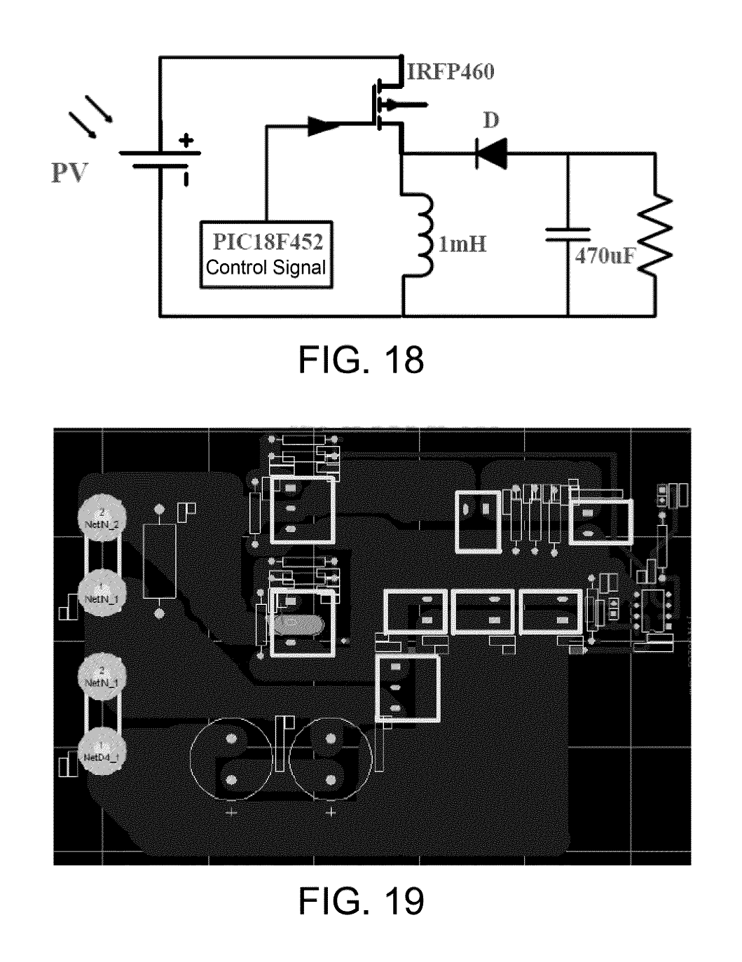

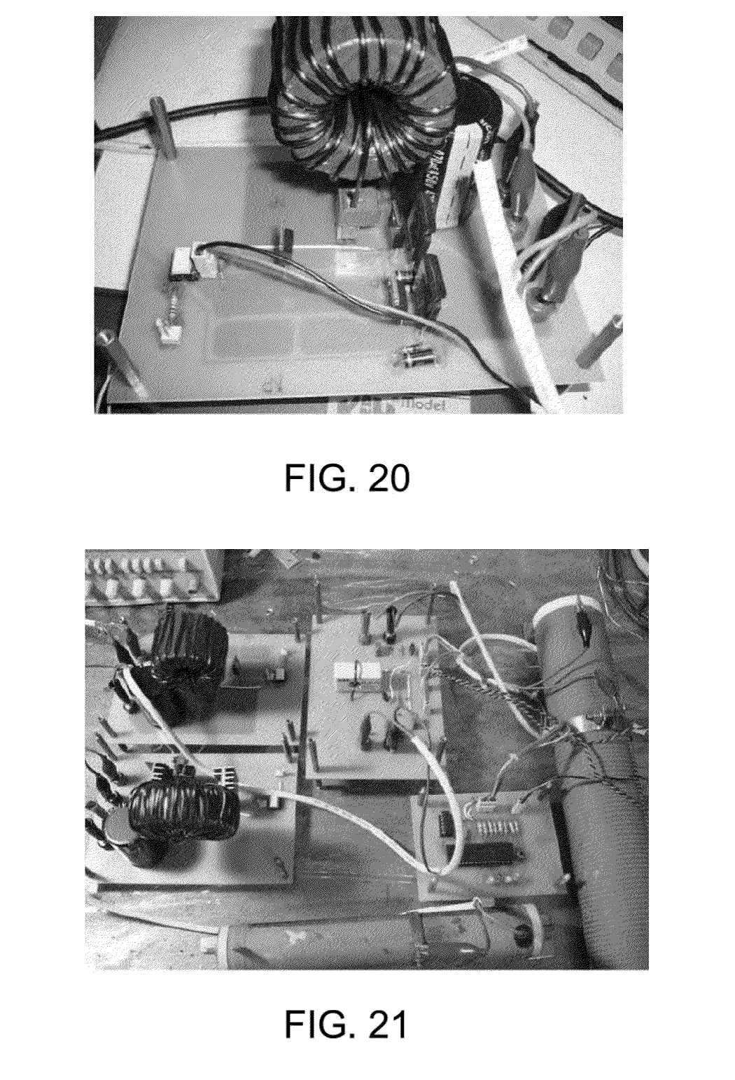

FIG. 15 is a schematic diagram of the overall system; FIGS. 16 and 17 are circuit diagrams and physical realizations of the voltage and current feedback circuits, respectively. The main circuit structure, design, physical realization and overall system for maximum power point tracking are shown in FIGS. 18, 19, 20 and 21, respectively.

### 5. Design and Implementation for Maximum Energy Utilization

The present invention employs 900 W independent PV system, which uses the perturbation and observation method for maximum power point tracking (MPPT) and interleaved operation to alternately generating voltages from two sets of DC-DC Buck-Boost converters, such that the problem that energy is not extracted from the PV system during turning-off period of the converter can be eliminated, thereby achieving maximum energy utilization.

### 5.1 Simulation of Circuit for Interleaved Operation

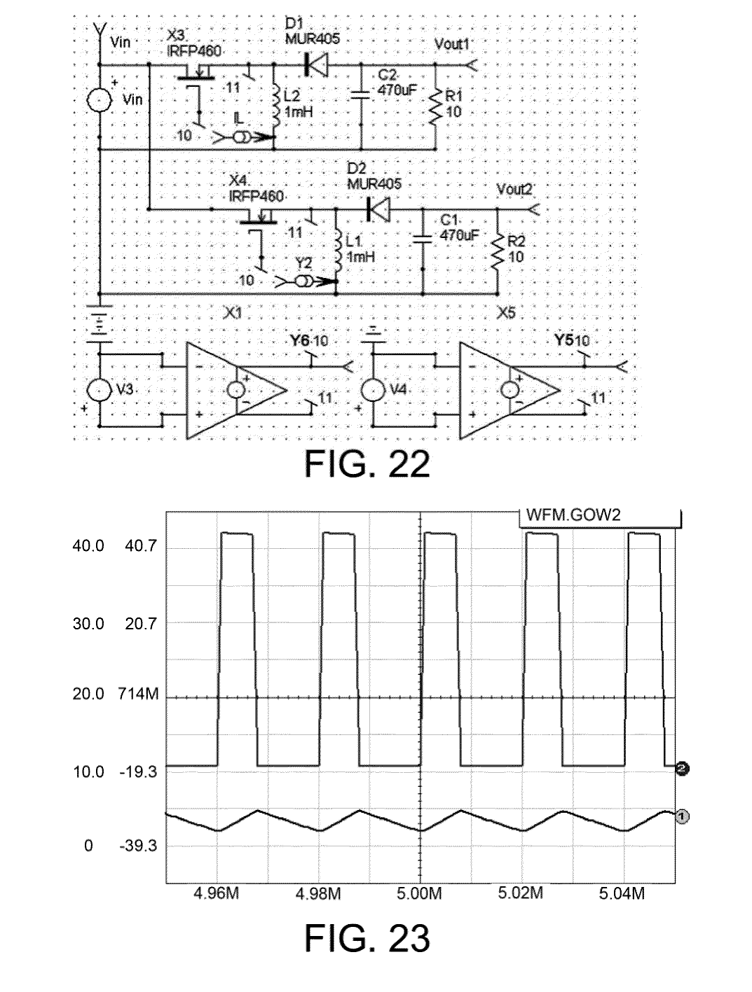

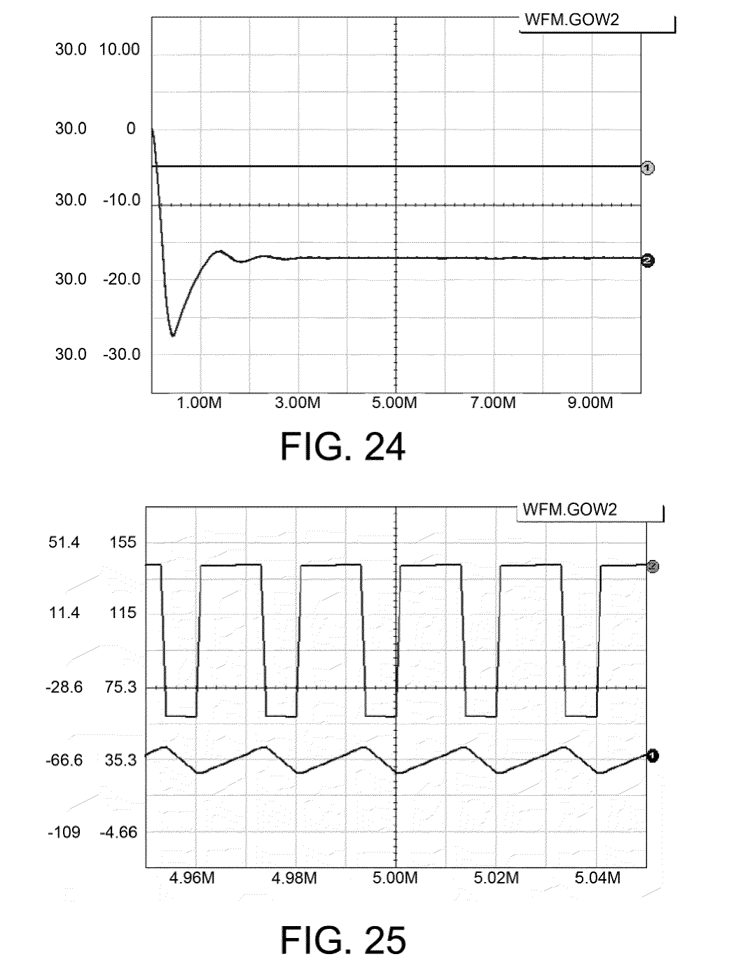

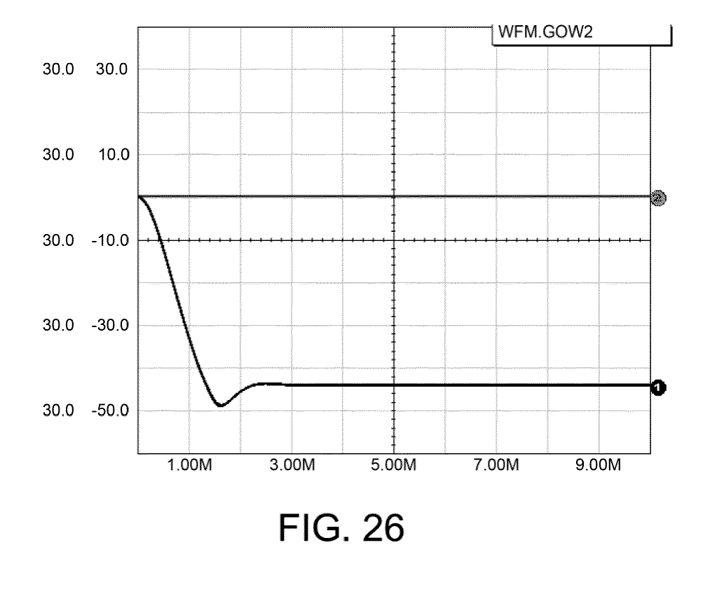

IsSpice is used to simulate the main circuit structure. As shown in FIG. 22, Vin is set to 30V; switching frequency of a switch (SWc) set to 50 kHz and resistor loading set to 10Ω. The simulated waveforms are shown in FIGS. 23, 24, 25 and 26.

### 5.2 Interleaved Operation

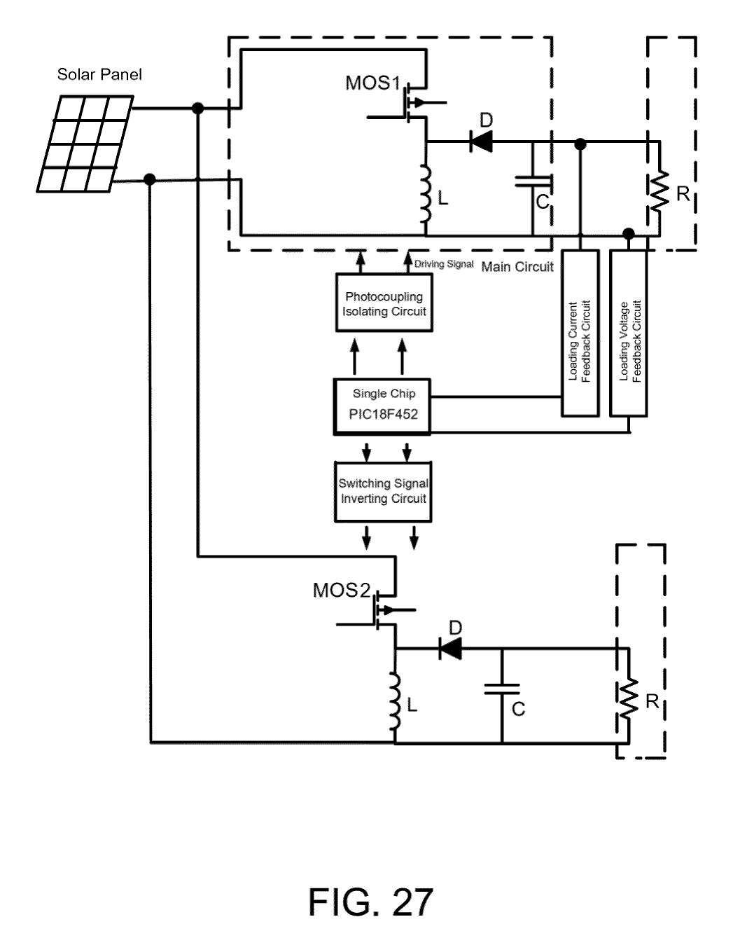

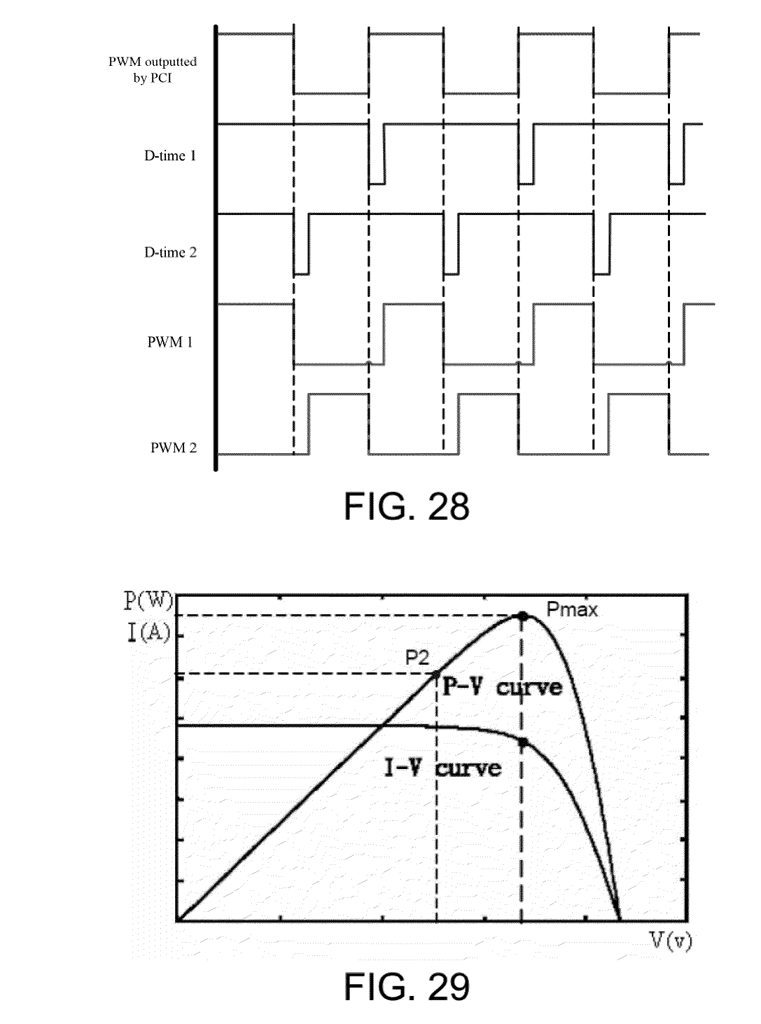

FIG. 27 is a solar energy independent powering system. First set of main circuit is a buck-boost converter. The MPPT technique is used to adjust the duty cycle of the switch (SWc) with a switching frequency of 50 kHz, such that the first set of main circuit can be operated at the maximum power point. The system includes two sets of buck-boost converters connected in parallel, which are controlled by interleaved operation shown in FIG. 28, thereby maximizing efficiency of energy conversion.

FIG. 28 is a diagram depicting the timing of the interleaved control operation for two buck-boost converters in the same period and same phase. The switching frequency is 50 kHz. Dead time is also added to avoid circuit error due to overlapping of the two switches.

The present invention includes the two buck-boost converters connected in parallel, one of which uses feedback control and perturbation and observation method for MMPT, so as to obtain the maximum power. The PWM output of the second converter is an inverted version of that of the first. The resistance at the loading end is appropriately selected, such that the second converter also obtains power close to the maximum power.

### 5.3 Discussion of Maximum Power Obtained by Two Sets of Converters

As shown in FIG. 27, the system includes two buck-boost converter and one maximum power point tracker. The parameters (L and C) of the elements used in the two converters are the same. FIG. 29 is a drawing depicting the characteristics curves of photovoltaics. Pmax is the maximum power point (MPP). In the present invention, the first converter can be operated at the MPP by using the perturbation and observation method. If the duty cycle is under 0.5 when the first loading reaches the MPP, a PWM signal that is the same with the first but shifted in phase by 180° is outputted by the second PWM built in the single chip PIC18F452, so that the switch of the second converter also has the same duty cycle, but its turn-on time is interleaved. Since the two converters and the loadings are the same, the two converters in theory should both obtain the maximum power.

However, after actual testing, it is found that when the first converter tracks the MPP under different irradiation, the duty cycle of the switch is greater than 0.5 if the loading is of some certain values. In this case, the duty cycle of switch in the second converter cannot be the same as that of the first; else there will be circuit error due to simultaneous turn-on.

After numerous experiments, it is found that under stable weather condition for which the changes in irradiation is not significant, the duty cycle can be made smaller than 0.5 by adjusting the resistance at the loading end. By careful load designing in advance, the output of both converters can be at or close to the maximum power. The second converter is auxiliary, thus design is made for situations when the duty cycle of the first converter is greater than 0.5.

### 5.3.1 Experimental Data for Maximum Power Tracking

The relationship between duty cycle and output impedance is found using a buck-boost converter. From the measurements shown in Tables 2, 3 and 4 under irradiance of 45K, 54K and 68K, respectively, and loading end resistance ranging from 4Ω to 40Ω, the changes of MPP duty cycle can be observed.

TABLE 2
Irradiance: 45K Lux/Solar Panel Title Angle: 20°/Weather: Sunny

| | | | Iout | | | Efficiency | |
|---|---|---|---|---|---|---|---|
| Vin (V) | Iin (A) | Vout (V) | (A) | P (W) | R (Ω) | (%) | Duty |
| 64.5 | 4.2 | 31 | 7.6 | 235.6 | 4 | 86.9 | 0.35 |
| 61 | 4.4 | 34.5 | 6.9 | 238.05 | 5 | 88.6 | 0.38 |
| 63 | 4.8 | 40 | 6.5 | 260 | 6 | 85.9 | 0.41 |
| 65.5 | 4.7 | 43 | 6.1 | 262.3 | 7 | 85.2 | 0.42 |
| 65.5 | 5.2 | 49 | 6.1 | 298.9 | 8 | 87.7 | 0.45 |
| 66.5 | 4.8 | 50.5 | 5.5 | 277.75 | 9 | 87 | 0.45 |
| 58.5 | 5.6 | 52.5 | 5.3 | 278.25 | 10 | 84.9 | 0.51 |
| 56.5 | 6.0 | 58 | 4.9 | 284.2 | 12 | 83.8 | 0.54 |
| 58.5 | 5.7 | 61.5 | 4.4 | 270.6 | 14 | 81.1 | 0.55 |
| 55 | 6.2 | 67.5 | 4.2 | 283.5 | 16 | 83.1 | 0.58 |
| 54 | 5.5 | 70 | 3.9 | 273 | 18 | 91.9 | 0.58 |
| 56.5 | 5.6 | 75 | 3.8 | 285 | 20 | 90.0 | 0.59 |
| 54 | 6.1 | 80.5 | 3.3 | 265.65 | 25 | 80.7 | 0.62 |
| 58.5 | 5.8 | 88.5 | 3.1 | 274.35 | 30 | 80.8 | 0.64 |
| 51.5 | 5.1 | 94 | 2.4 | 225.6 | 40 | 85.8 | 0.67 |

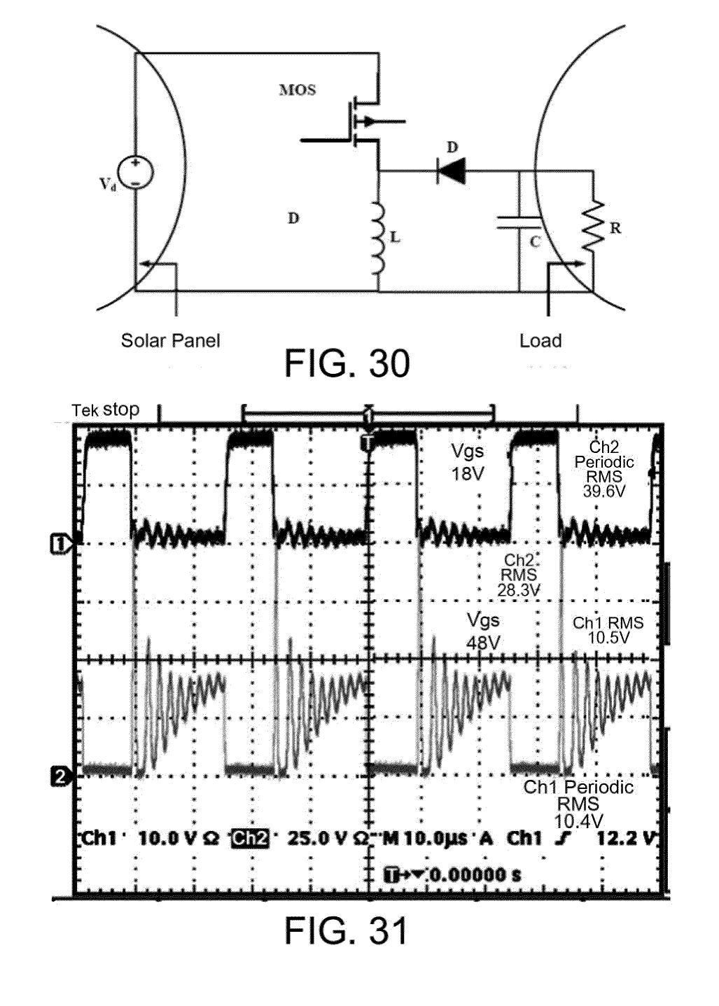

In Tables 2, 3 and 4, the output resistances are varied in order to observe whether the change in resistance is related to the duty cycle of the MPPT switch. From the data, it can be seen that there is a relationship between them, which can be explained through “impedance matching rule”, as indicated by the formula below and in conjunction with FIG. 30:

$$\frac{{V}_{out}}{{I}_{out}} = {( \frac{D}{1 - D} )}^{2} * \frac{{V}_{i n}}{{I}_{i n}}$$

wherein Vout/Iout=output impedance and Vin/Iin=input impedance.

TABLE 3
Irradiance: 54K Lux/Solar Panel Title Angle: 20°/Weather: Sunny

| | | | Iout | | | Efficiency | |
|---|---|---|---|---|---|---|---|
| Vin (V) | Iin (A) | Vout (V) | (A) | P (W) | R (Ω) | (%) | Duty |
| 65.7 | 4.9 | 34.5 | 8.2 | 282.9 | 4 | 87.8 | 0.36 |
| 66.6 | 4.7 | 38 | 7.5 | 285 | 5 | 91.0 | 0.38 |
| 76.9 | 4.4 | 42 | 7.1 | 298.2 | 6 | 88.1 | 0.36 |
| 71.5 | 4.7 | 45.5 | 6.5 | 295.75 | 7 | 88.0 | 0.4 |
| 65.2 | 5.2 | 48 | 6.1 | 292.8 | 8 | 8603 | 0.44 |
| 61 | 5.4 | 50 | 5.5 | 275 | 9 | 83.4 | 0.47 |
| 54.5 | 5.5 | 52 | 5.2 | 270.4 | 10 | 90.2 | 0.51 |
| 55 | 5.2 | 55 | 4.6 | 253 | 12 | 88.4 | 0.52 |
| 56.4 | 4.5 | 59 | 3.9 | 230.1 | 14 | 90.6 | 0.55 |
| 52.6 | 4.6 | 70.6 | 3.2 | 225.92 | 16 | 93.3 | 0.56 |
| 57.2 | 4.5 | 71 | 3.2 | 227.2 | 18 | 88.2 | 0.59 |
| 50.5 | 6.6 | 75.5 | 3.8 | 286.9 | 20 | 86.0 | 0.62 |
| 49.5 | 6.2 | 81 | 3.3 | 267.3 | 25 | 87.0 | 0.64 |
| 54.5 | 6.1 | 91 | 3.1 | 282.1 | 30 | 84.8 | 0.65 |
| 53.5 | 5.4 | 94.5 | 2.4 | 226.8 | 40 | 78.5 | 0.68 |

When the irradiance and temperature are fairly stable, input impedances (Vin/Iin) are almost constant, thus the greater the output impedance, the greater the D value, and vice versa. The above equation defines the relationship between the output impedance and the D value. As previously mentioned in the beginning of this section, by carefully designing the loadings of the two converters, both converters can obtain maximum or near maximum power. The loading resistance that ensures the duty cycle is smaller 0.5 when obtaining MPP is empirically determined using experimental data.

TABLE 4
Irradiance: 68K Lux/Solar Panel Title Angle: 20°/Weather: Sunny

| | | | Iout | | | Efficiency | |
|---|---|---|---|---|---|---|---|
| Vin (V) | Iin (A) | Vout (V) | (A) | P (W) | R (Ω) | (%) | Duty |
| 55.5 | 6.1 | 35 | 8.6 | 301 | 4 | 88.9 | 0.4 |
| 57 | 6.1 | 39 | 8 | 312 | 5 | 89.7 | 0.42 |
| 54.5 | 6.3 | 42 | 7.2 | 302.4 | 6 | 88.0 | 0.45 |
| 60.5 | 5.8 | 47 | 6.7 | 314.9 | 7 | 89.7 | 0.45 |
| 56.5 | 6.1 | 49 | 6.2 | 303.8 | 8 | 88.1 | 0.48 |
| 53.5 | 6.4 | 52.5 | 5.9 | 309.75 | 9 | 90.4 | 0.51 |
| 54 | 6.2 | 55.5 | 5.5 | 305.25 | 10 | 91.1 | 0.52 |
| 58 | 5.7 | 60 | 4.9 | 294 | 12 | 88.9 | 0.52 |
| 55.5 | 5.8 | 62.5 | 4.5 | 281.25 | 14 | 87.3 | 0.55 |
| 54.5 | 6.0 | 67.5 | 4.2 | 283.5 | 16 | 86.6 | 0.58 |
| 55 | 6.6 | 76 | 4.2 | 319.2 | 18 | 87.9 | 0.6 |
| 55.5 | 6.1 | 78 | 3.9 | 304.2 | 20 | 89.8 | 0.6 |
| 51.5 | 6.5 | 85 | 3.4 | 289 | 25 | 86.3 | 0.64 |
| 51.5 | 6.4 | 90.5 | 3.0 | 271.5 | 30 | 82.3 | 0.66 |
| 58.5 | 5.7 | 104.5 | 2.6 | 271.7 | 40 | 81.4 | 0.72 |

Formulae of the buck-boost converter (true when inductive current operating under CCM mold):

$$\begin{matrix}{V}_{out} = \frac{D}{1 - D} * {V}_{i n} & ( 5.1 ) \\ {I}_{out} = \frac{1 - D}{D} * {I}_{i n} & ( 5.2 )\end{matrix}$$

Formula (5.1) is divided by formula (5.2) to obtain formula (5.3) below:

$$\frac{{V}_{out}}{{I}_{out}} = {( \frac{D}{1 - D} )}^{2} * \frac{{V}_{i n}}{{I}_{i n}} \qquad ( 5.3 )$$

wherein Vin is input voltage, Iin is input current, Vout is output voltage, lout is output current, and D is duty cycle.

### 5.3.2 Experimental Output Data for Two Sets of Converters

Tables 5 and 6 are the experimental output data for the solar energy power system including the two sets of converters, wherein the two converters use the same elements and the same loading resistances. As can be seen in tables 5 and 6 under irradiance of 56K and 70K, respectively, when no loading resistance matching design is made in advance, the energy obtained by the second converter is much lower than that obtained by the first. Such loading is too far away from the duty cycle of the MPP switch, as shown in FIG. 29, the operating point falls at P2, but P2 should be made as close to Pmax as possible for achieving the largest efficiency.

TABLE 5
Irradiance: 56K Lux/Solar Panel Tilt Angle: 20°/Weather: Sunny

| Exp. | Set | Vout (V) | Iout (A) | P (W) | R (Ω) | Duty |
|---|---|---|---|---|---|---|
| 1 | 1 | 54 | 4.8 | 259.2 | 10 | 0.54 |
| | 2 | 38.5 | 3.1 | 119.35 | 10 | 0.36 |
| 2 | 1 | 66.5 | 4.1 | 272.65 | 15 | 0.56 |
| | 2 | 39 | 3.0 | 117 | 15 | 0.34 |
| 3 | 1 | 76 | 3.8 | 288.8 | 20 | 0.63 |
| | 2 | 22 | 2.7 | 59.4 | 20 | 0.27 |
| 4 | 1 | 80.5 | 3.3 | 265.65 | 25 | 0.63 |
| | 2 | 20.5 | 2..2 | 45.1 | 25 | 0.27 |
| 5 | 1 | 88.5 | 3.2 | 283.2 | 30 | 0.67 |
| | 2 | 28.5 | 2.4 | 68.4 | 30 | 0.23 |
| 6 | 1 | 91 | 2.7 | 245.7 | 35 | 0.68 |
| | 2 | 18 | 1.5 | 27 | 35 | 0.22 |
| 7 | 1 | 96.5 | 2.2 | 212.3 | 40 | 0.7 |
| | 2 | 16.5 | 1.1 | 18.15 | 40 | 0.2 |
| 8 | 1 | 108 | 2.0 | 216 | 45 | 0.7 |
| | 2 | 16.5 | 1.1 | 18.15 | 45 | 0.2 |

TABLE 6
Irradiance: 70K Lux/Solar Panel Tilt Angle: 20°/Weather: Sunny

| Exp. | Set | Vout (V) | Iout (A) | P (W) | R (Ω) | Duty |
|---|---|---|---|---|---|---|
| 1 | 1 | 54 | 4.8 | 259.2 | 10 | 0.54 |
| | 2 | 38.5 | 3.1 | 119.35 | 10 | 0.36 |
| 2 | 1 | 66.5 | 4.1 | 272.65 | 15 | 0.56 |
| | 2 | 39 | 3.0 | 117 | 15 | 0.34 |
| 3 | 1 | 76 | 3.8 | 288.8 | 20 | 0.63 |
| | 2 | 22 | 2.7 | 59.4 | 20 | 0.27 |
| 4 | 1 | 80.5 | 3.3 | 265.65 | 25 | 0.63 |
| | 2 | 20.5 | 2..2 | 45.1 | 25 | 0.27 |
| 5 | 1 | 88.5 | 3.2 | 283.2 | 30 | 0.67 |
| | 2 | 28.5 | 2.4 | 68.4 | 30 | 0.23 |
| 6 | 1 | 91 | 2.7 | 245.7 | 35 | 0.68 |
| | 2 | 18 | 1.5 | 27 | 35 | 0.22 |
| 7 | 1 | 96.5 | 2.2 | 212.3 | 40 | 0.7 |
| | 2 | 16.5 | 1.1 | 18.15 | 40 | 0.2 |
| 8 | 1 | 108 | 2.0 | 216 | 45 | 0.7 |
| | 2 | 16.5 | 1.1 | 18.15 | 45 | 0.2 |

Therefore, if the loading resistance of the second converter is not carefully selected but made to be the same as that of the first converter, the energy obtained may be much lower.

In tables 7 and 8 below, the loading resistance of the second converter is carefully designed, not only to make the duty cycle complementary, but also allowing P2 to be as close to Pmax as possible. From these data, it can be seen that the power of the second set is higher than that without resistance matching. In addition to traditional MPPT, interleaving of duty cycle is performed to obtain more energy. Moreover, loading end resistance of the second converter is carefully chosen to improve the efficiency of energy conversion.

TABLE 7
Irradiance: 56K Lux/Solar Panel Tilt Angle: 20°/Weather: Sunny

| Exp. | Set | Vout (V) | Iout (A) | P (W) | R (Ω) | Duty |
|---|---|---|---|---|---|---|
| 1 | 1 | 54 | 4.8 | 259.2 | 10 | 0.54 |
| | 2 | 42.5 | 3.0 | 127.5 | 5 | 0.36 |
| 2 | 1 | 66.5 | 4.1 | 272.65 | 15 | 0.56 |
| | 2 | 41 | 2.9 | 118.9 | 5 | 0.34 |
| 3 | 1 | 76 | 3.8 | 288.8 | 20 | 0.63 |
| | 2 | 39 | 3.1 | 120.9 | 4 | 0.27 |
| 4 | 1 | 80.5 | 3.3 | 265.65 | 25 | 0.63 |
| | 2 | 78.5 | 3.1 | 243.35 | 4 | 0.27 |
| 5 | 1 | 88.5 | 3.2 | 283.2 | 30 | 0.67 |
| | 2 | 41.5 | 2.9 | 120.35 | 4 | 0.23 |
| 6 | 1 | 91 | 2.7 | 245.7 | 35 | 0.68 |
| | 2 | 37 | 2.9 | 107.3 | 4 | 0.22 |
| 7 | 1 | 96.5 | 2.2 | 212.3 | 40 | 0.7 |
| | 2 | 35 | 3.1 | 108.5 | 4 | 0.2 |
| 8 | 1 | 108 | 2.0 | 216 | 45 | 0.7 |
| | 2 | 35 | 3.1 | 108.5 | 4 | 0.2 |

TABLE 8
Irradiance: 70K Lux/Solar Panel Tilt Angle: 20°/Weather: Sunny

| Exp. | Set | Vout (V) | Iout (A) | P (W) | R (Ω) | Duty |
|---|---|---|---|---|---|---|
| 1 | 1 | 56.5 | 5.5 | 310.75 | 10 | 0.54 |
| | 2 | 45 | 3.5 | 157.5 | 6 | 0.36 |
| 2 | 1 | 64 | 4.7 | 300.8 | 15 | 0.57 |
| | 2 | 44 | 3.4 | 149.6 | 5 | 0.33 |
| 3 | 1 | 74.5 | 4.1 | 305.45 | 20 | 0.61 |
| | 2 | 40.5 | 2.8 | 113.4 | 5 | 0.29 |
| 4 | 1 | 86 | 3.6 | 309.6 | 25 | 0.65 |
| | 2 | 40.5 | 2.8 | 113.4 | 4 | 0.25 |
| 5 | 1 | 90.5 | 3.5 | 316.75 | 30 | 0.68 |
| | 2 | 42.5 | 2.5 | 106.25 | 4 | 0.22 |
| 6 | 1 | 95.5 | 3.4 | 324.7 | 35 | 0.72 |
| | 2 | 30.5 | 2.0 | 61 | 4 | 0.18 |
| 7 | 1 | 106 | 2.9 | 307.4 | 40 | 0.76 |
| | 2 | 24 | 1.8 | 43.2 | 4 | 0.14 |
| 8 | 1 | 111 | 2.8 | 310.8 | 45 | 0.76 |
| | 2 | 24 | 1.8 | 43.2 | 4 | 0.14 |

From tables 7 and 8, it can also be observed that when the duty cycle of the first set is at 0.7, the turn-on time of the second set is very short, even after resistance matching. Thus, if the efficiency of the second convert is to be higher, then the duty cycle of the first set should not be larger than 0.7.

5.4 Waveforms Obtained from Actual Implementations

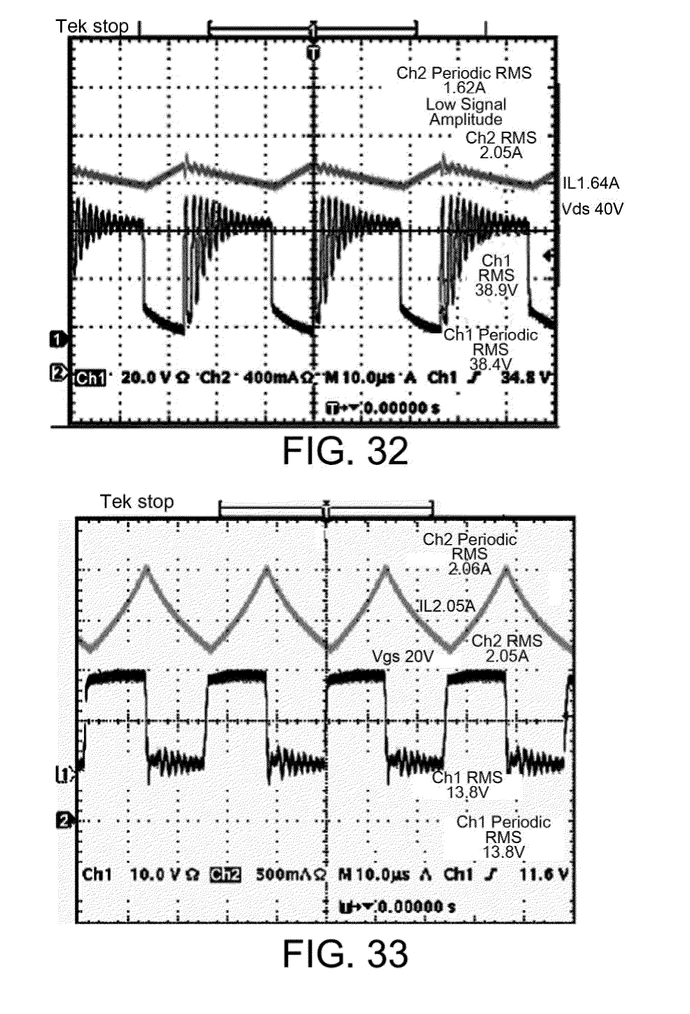

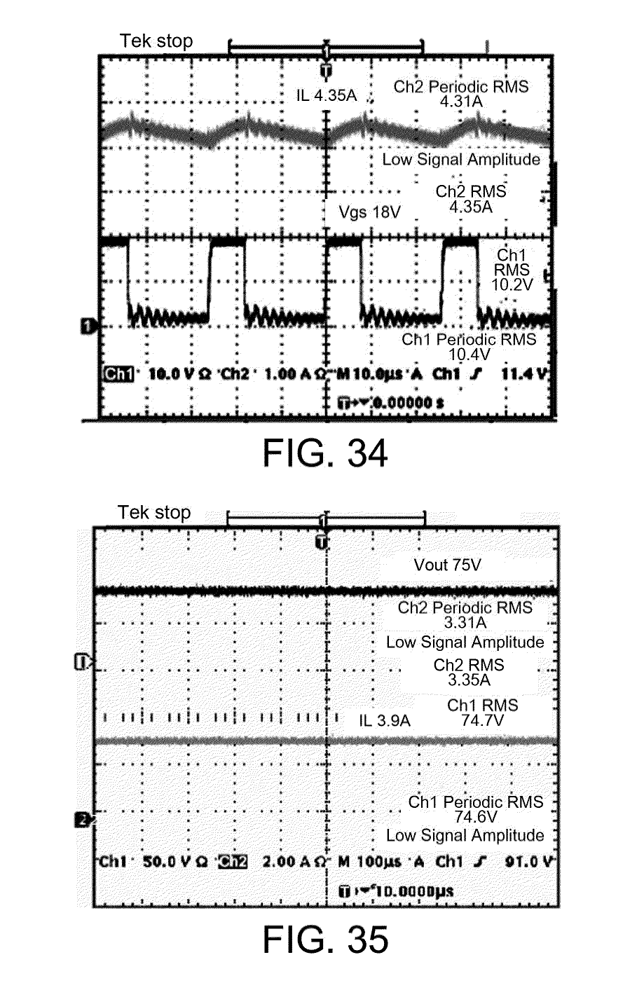

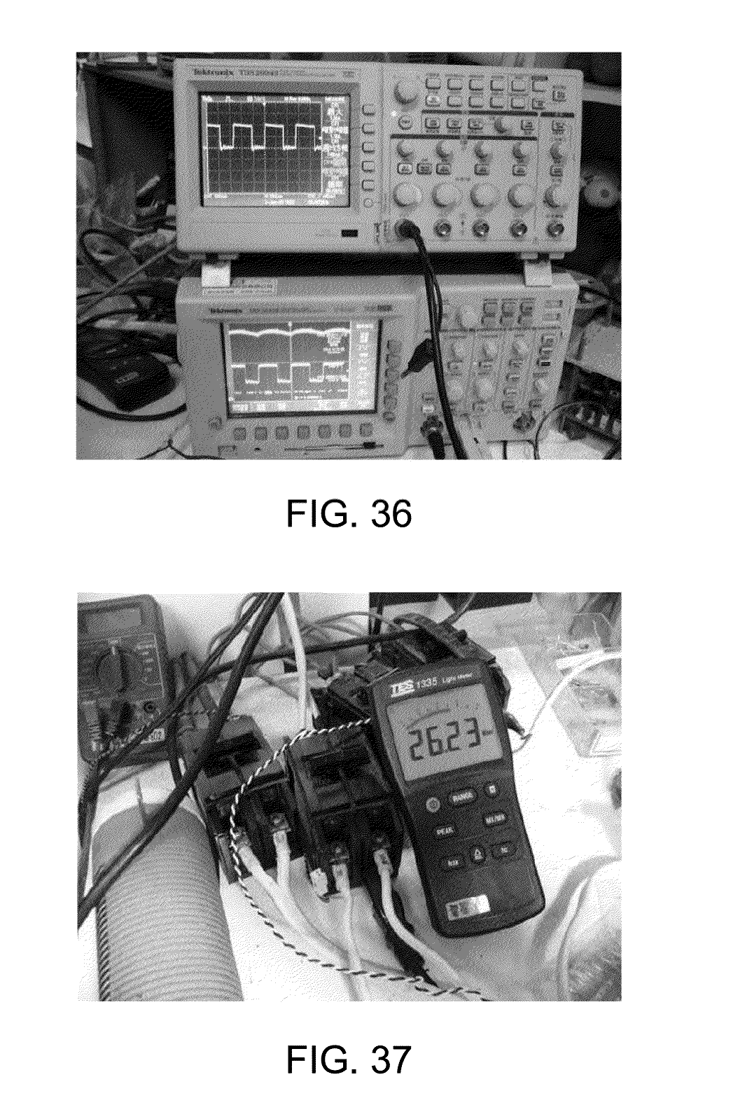

FIG. 31 shows the waveforms of Vgs and Vds of the switch MOS. FIG. 32 shows the waveform of Vds and inductive current of about 1.6 A of the switch MOS. FIGS. 33 and 34 are waveforms of Vds and inductive currents of the first and second set of switch MOS, respectively, with total of the two switching signals not over 1. FIG. 35 shows the output DC voltage and current waveforms. FIG. 36 is a diagram of the oscilloscope used. FIG. 37 is a luxmeter and a switch of a solar energy input end.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the inventions as determined by the appended claims when interpreted in accordance with the breath to which they are fairly and legally entitled.

It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

What is claimed is:

1. A solar energy system, comprising:
a solar panel for converting light into electricity;
a plurality of converters electrically coupled with the solar panel; and
a controller electrically coupled with the plurality of converters for controlling the duty cycles of switches of the plurality of converters respectively, when the switch of an arbitrary one of the converters being switched on by the controller, the rest of the converters being switched off.

2. A solar energy system of claim 1, wherein the controller includes at least one single chip and at least one photocoupler.

3. A solar energy system of claim 2, further comprising a voltage feedback circuit electrically coupled to an arbitrary one of the converters and the single chip.

4. A solar energy system of claim 3, further comprising a current feedback circuit electrically coupled to an arbitrary one of the converters and the single chip.

5. A solar energy system of claim 3, further comprising a dead-time generating circuit electrically coupled to the single chip.

6. A solar energy system of claim 1, wherein the plurality of converters are selected from one or a combination of the following types: buck, boost, buck-boost, cuk, flyback, forward, push-pull, Sheppard-Taylor, half-bridge and full-bridge.

7. A solar energy system, comprising:
a solar panel for converting light into electricity;
a first converter electrically coupled with the solar panel;
a second converter electrically coupled with the first converter in a parallel manner; and
a controller electrically coupled with the first and second converters for controlling the duty cycles of switches of the first and second converters respectively, when the switch of the first converter being switched on by the controller, the second converter being switched off.

8. A solar energy system of claim 7, wherein the controller includes at least one single chip and at least two photocouplers.

9. A solar energy system of claim 7,wherein the controller includes a single chip, a first photocoupling isolating circuit and a second photocoupling isolating circuit, wherein the single chip is electrically coupled to the first and second photocoupling isolating circuits respectively, the first photocoupling isolating circuit being electrically coupled to the first converter, and the second photocoupling isolating circuit being electrically coupled to the second converter, the single chip sending a first driving signal to the first photocoupling isolating circuit and a second driving signal to the second photocoupling isolating circuit, the first driving signal being out of phase with the second driving signal.

10. A solar energy system of claim 9, further comprising a voltage feedback circuit electrically coupled to an arbitrary one of the converters and the single chip.

11. A solar energy system of claim 9, further comprising a current feedback circuit electrically coupled to an arbitrary one of the converters and the single chip.

12. A solar energy system of claim 9, further comprising a dead-time generating circuit electrically coupled to the single chip.

13. A solar energy system of claim 9, wherein after the single chip sending the first driving signal to the first photocoupling isolating circuit, the first photocoupling isolating circuit receiving the first driving signal and generating a light source, the switching on and off of the switch of the first converter being controlled by the intensity of the light source.

14. A solar energy system of claim 13, wherein the first driving signal is a pulse width modulation (PWM) signal.

15. A solar energy system of claim 9, wherein after the single chip sending the second driving signal to the second photocoupling isolating circuit, the second photocoupling isolating circuit receiving the second driving signal and generating a light source, the switching on and off of the switch of the second converter being controlled by the intensity of the light source.

16. A solar energy system of claim 15, wherein the second driving signal is a pulse width modulation (PWM) signal.

17. A solar energy system of claim 7, wherein the first and second converters are selected from one or a combination of the following types: buck, boost, buck-boost, cuk, flyback, forward, push-pull, Sheppard-Taylor, half-bridge and full-bridge.

18. A method for producing energy from a solar energy system, comprising:
performing a light-to-electricity converting process by converting light into electricity using a solar panel;
performing an electricity converting process by alternately using two converters to provide electricity to a load, the two converters being a first and a second converter;
performing a determining process, in which a controller modulates the duty cycle of a switch of the first converter after receiving a voltage and a current from the first converter, the duty cycle of a switch of the second converter being in cooperation with the switch of the first converter, when the controller switching on the switch of the first converter, the switch of the second converter being switched off; whereas when the controller switching off the switch of the first converter, the switch of the second converter being switched on.

19. A method for producing energy from a solar energy system of claim 18, wherein the determining process includes a controller receiving a voltage and a current sent from the first converter and calculating the best duty cycle required for the switch of the first converter, thereby obtaining maximum power throughput.
